(19) United States
(12) Patent Application Publication
(10) Pub. No.: US 2026/0163498 A1
(43) Pub. Date: Jun. 11, 2026

(54) SEMICONDUCTOR MODULE AND POWER CONVERSION APPARATUS

(71) Applicant: DENSO CORPORATION, Kariya-city (JP)

(72) Inventor: Masataka DEGUCHI, Kariya-city (JP)

(73) Assignee: DENSO CORPORATION, Kariya-city (JP)

(21) Appl. No.: 19/465,260

(22) Filed: Jan. 30, 2026

Related U.S. Application Data
(63) Continuation of application No. PCT/JP2024/025189, filed on Jul. 12, 2024.

(30) Foreign Application Priority Data
Aug. 3, 2023 (JP) 2023-127316

(51) Int. Cl. H02M 7/5395; H02M 7/493; H02P 27/00; H10W 70/65

(52) U.S. Cl. CPC H02M 7/5395; H02M 7/493; H10W 70/658; H02P 27/00

(57) ABSTRACT

A semiconductor module is included in two inverters connected to a common rotating electric machine. The module has a first semiconductor element, a second semiconductor element, a first current path, and a second current path. The first semiconductor element is in a first inverter, and the second semiconductor element is in a second inverter. The second inverter has at least part of an ON period that overlaps with the ON period of the first semiconductor element. The first current path includes the first semiconductor element, and the second current path includes the second semiconductor element. The second semiconductor element is adjacent to the first semiconductor element in a predetermined direction. The first and second current paths are disposed side by side in the predetermined direction, with opposite current flow directions through the first and second current paths.

### CROSS REFERENCE TO RELATED APPLICATIONS

The present application is a continuation application of International Patent Application No. PCT/JP2024/025189 filed on Jul. 12, 2024, which designated the U.S. and claims the benefit of priority from Japanese Patent Application No. 2023-127316 filed on Aug. 3, 2023. The entire disclosures of all of the above applications are incorporated herein by reference.

### TECHNICAL FIELD

The present disclosure relates to a semiconductor module and a power conversion apparatus.

### BACKGROUND

A power conversion apparatus may include two inverters connected to a common rotating electric machine.

### SUMMARY

According to an aspect of the present disclosure, a semiconductor module is included in two inverters that are connected to a common rotating electric machine. The semiconductor module includes a first semiconductor element, a second semiconductor element, a first current path, and a second current path. The first semiconductor element is included in a first inverter that is one of the two inverters. The second semiconductor element is included in a second inverter that is another of the two inverters. The second inverter has at least a portion of an ON period that overlaps with an ON period of the first semiconductor element. The first current path includes the first semiconductor element. The second current path includes the second semiconductor element. The second semiconductor element may be adjacent to the first semiconductor element in a predetermined direction. The first current path and the second current path may be disposed side by side in the predetermined direction, such that a direction of current flow through the first current path and a direction of current flow through the second current path are opposite to each other.

### BRIEF DESCRIPTION OF DRAWINGS

FIG. 1 is a diagram illustrating a drive system according to a first embodiment.

FIG. 2 is a diagram illustrating an example of an operating point map of a rotating electric machine.

FIG. 3 is a diagram illustrating star connection drive.

FIG. 4 is a diagram illustrating open connection drive.

FIG. 5 is a plan view illustrating an example of a power conversion apparatus.

FIG. 6 is a plan view illustrating an example of a semiconductor module.

FIG. 7 is a plan view illustrating another example of a semiconductor device.

FIG. 8 is a plan view illustrating another example of the semiconductor device.

FIG. 9 is a plan view illustrating another example of the semiconductor device.

FIG. 10 is a plan view illustrating another example of the semiconductor device.

FIG. 11 is a diagram illustrating flux cancellation during the open connection drive.

FIG. 12 is a diagram illustrating flux cancellation during the star connection drive.

FIG. 13 is a diagram illustrating a drive system according to a second embodiment.

FIG. 14 is a plan view illustrating an example of the semiconductor module.

### DETAILED DESCRIPTION

An inverter may include a semiconductor module having a semiconductor element. In a power conversion apparatus in a related field, for example, a first inverter includes a first semiconductor module, and a second inverter includes a second semiconductor module. In this configuration, when current flows between the first inverter and the second inverter, the current may also flow between the first semiconductor module and the second semiconductor module, resulting in an issue of high inductance. From the above-mentioned perspective, or from other perspectives not referred to, further improvements are desired for semiconductor modules and power conversion apparatus.

According to an aspect of the present disclosure, a semiconductor module is included in two inverters that are connected to a common rotating electric machine. The semiconductor module includes a first semiconductor element, a second semiconductor element, a first current path, and a second current path. The first semiconductor element is included in a first inverter that is one of the two inverters. The second semiconductor element is included in a second inverter that is another of the two inverters. The second inverter has at least a portion of an ON period that overlaps with an ON period of the first semiconductor element. The first current path includes the first semiconductor element. The second current path includes the second semiconductor element. The second semiconductor element is adjacent to the first semiconductor element in a predetermined direction. The first current path and the second current path are disposed side by side in the predetermined direction, such that a direction of current flow through the first current path and a direction of current flow through the second current path are opposite to each other.

According to the disclosed semiconductor module, with the above arrangement, when both the first semiconductor element and the second semiconductor element are turned on, the current flowing through the first current path and the current flowing through the second current path are in opposite direction. Therefore, by canceling out the magnetic flux, the inductance can be reduced.

According to another aspect of the present disclosure, a power conversion apparatus includes: a first inverter connected to a rotating electric machine; and a second inverter connected to the rotating electric machine. The first inverter and the second inverter include a semiconductor module. The semiconductor module includes a first semiconductor element, a second semiconductor element, a first current path, and a second current path. The first semiconductor element is included in a first inverter. The second semiconductor element is included in a second inverter. The second inverter has at least a portion of an ON period that overlaps with an ON period of the first semiconductor element. The first current path includes the first semiconductor element. The second current path includes the second semiconductor element. The second semiconductor element is adjacent to the first semiconductor element in a predetermined direction. The first current path and the second current path are disposed side by side in the predetermined direction, such that a direction of current flow through the first current path and a direction of current flow through the second current path are opposite to each other.

According to the disclosed power conversion apparatus, with the above arrangement, when both the first semiconductor element and the second semiconductor element are turned on, the current flowing through the first current path and the current flowing through the second current path are in opposite direction. Therefore, by canceling out the magnetic flux, the inductance can be reduced.

Hereinafter, multiple embodiments will be described with reference to the drawings. It should be noted that, in the respective embodiments, corresponding components are designated by the same reference numerals, and redundant explanations may be omitted. In cases where only a part of a configuration is described in each embodiment, the configuration of other parts previously described in other embodiments may be applied to those portions. Furthermore, in the descriptions of each embodiment, not only the explicitly stated combinations of configurations, but also partial combinations of configurations from multiple embodiments that are not explicitly stated may be adopted, provided there is no hindrance to such combinations. It should be noted that the phrase “A and/or B” means at least one of A and B. In other words, it may include only A, only B, or both A and B.

The semiconductor device of the present embodiment, and a semiconductor module including such a semiconductor device, may be applied, for example, to a power conversion apparatus for a moving object that uses a rotating electric machine as a drive source. Examples of the moving object include electric vehicles (BEVs), hybrid vehicles (HEVs), plug-in hybrid vehicles (PHEVs), and other electric vehicles; aircraft such as electric vertical take-off and landing (eVTOL) vehicles and drones; as well as ships, construction machines, and agricultural machines.

### First Embodiment

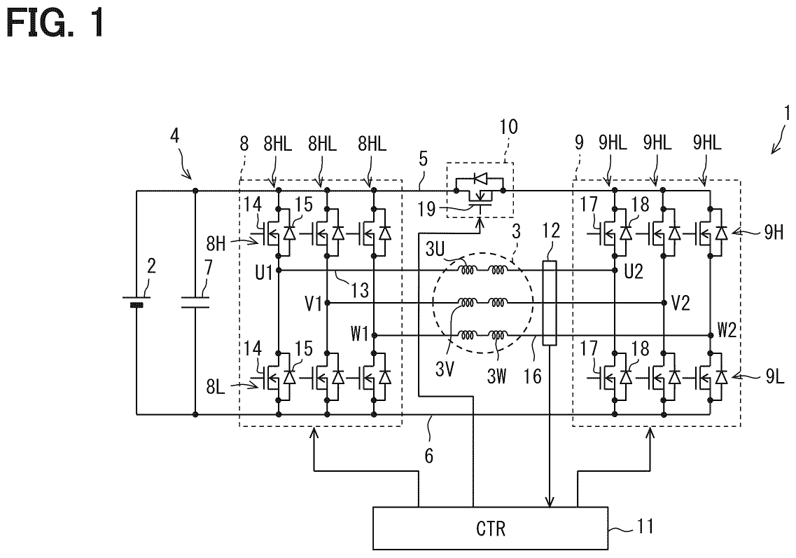

First, with reference to FIG. 1, the schematic configuration of the drive system for the moving object will be described.

### (Drive System of Moving Object)

As shown in FIG. 1, a drive system 1 of the moving object includes a DC power supply 2, a rotating electric machine 3, and a power conversion circuit 4.

The DC power supply 2 may be, for example, a rechargeable secondary battery such as a lithium-ion battery or a nickel-metal hydride battery. The DC power supply 2 may also be one that converts AC power into DC power and outputs the converted power.

The rotating electric machine 3 is a three-phase rotating electric machine of the open winding type with a neutral point left disconnected. The rotating electric machine 3 has a U-phase winding 3U, a V-phase winding 3V, and a W-phase winding 3W. Hereinafter, the U-phase winding 3U, V-phase winding 3V, and W-phase winding 3W may be simply referred to as windings 3U, 3V, and 3W.

The rotating electric machine 3 functions, for example, as a drive source for a moving object, that is, as an electric motor. When the moving object is a vehicle, the rotating electric machine 3 generates torque to drive wheels (not shown). The rotating electric machine 3 is not limited to being an electric motor. The rotating electric machine 3 may be a motor-generator having both motor and generator functions, or it may be a generator.

The power conversion circuit 4 performs power conversion between the DC power supply 2 and the rotating electric machine 3. The drive system 1 is a power supply common system in which electric power is supplied to two inverters 8 and 9, described later, from a common DC power supply 2. As illustrated in FIG. 1, the drive system 1 may be provided with only a single common DC power supply 2, or may be provided with multiple DC power supplies. The drive system 1 may be provided with a power supply switch, such as an SMR (not shown), between the DC power supply 2 and the power conversion circuit 4. SMR is an abbreviation for System Main Relay. By turning on the power supply switch, power can be supplied from the DC power supply 2 to the rotating electric machine 3, and by turning off the power supply switch, power supply from the DC power supply 2 to the rotating electric machine 3 is interrupted.

### (Power Conversion Circuit)

FIG. 1 shows an example of the power conversion circuit 4. The power conversion circuit 4 exemplified in FIG. 1 includes, as elements related to power conversion, power supply lines 5 and 6, a smoothing capacitor 7, inverters 8 and 9, a switch 10, a control unit 11, and a current sensor 12.

The power supply line 5 is a power supply line on the high potential side. The power supply line 5 is connected to a positive terminal of the DC power supply 2. The power supply line 6 is a power supply line on the low potential side. The power supply line 6 is connected to a negative terminal of the DC power supply 2. The power supply lines 5 and 6 are provided, for example, by bus bars made of metal plate material.

The smoothing capacitor 7 primarily smooths the DC voltage supplied from the DC power supply 2. The smoothing capacitor 7 is provided between the power supply lines 5 and 6. The positive terminal of the smoothing capacitor 7 is connected to the power supply line 5 between the DC power supply 2 and the inverters 8 and 9. The negative terminal of the smoothing capacitor 7 is connected to the power supply line 6 between the DC power supply 2 and the inverters 8 and 9. The smoothing capacitor 7 is connected in parallel with the inverters 8 and 9.

The inverters 8 and 9 are DC-AC conversion circuits. The inverter 8 includes upper and lower arm circuits 8HL for three phases. The upper and lower arm circuits 8HL are sometimes referred to as legs. The upper and lower arm circuits 8HL include an upper arm 8H and a lower arm 8L. The upper arm 8H and lower arm 8L are connected in series between the power supply lines 5 and 6, with the upper arm 8H on the power supply line 5 side.

The connection node between the upper arm 8H and the lower arm 8L is connected to the winding of the corresponding phase in the rotating electric machine 3 via an output line 13. The inverter 8 has six arms. Each arm includes a switching element. The number of switching elements included in each arm is not particularly limited. There may be only one, or there may be multiple. In the case of multiple switching elements, the switching elements connected in parallel to each other are driven on and off at the same period by a common gate drive signal (drive voltage).

In the example shown in FIG. 1, an n-channel type MOSFET 14 is employed as the switching element included in each arm. MOSFET stands for Metal Oxide Semiconductor Field Effect Transistor. In the upper arm 8H, the drain of the MOSFET 14 is connected to the power supply line 5. In the lower arm 8L, the source of the MOSFET 14 is connected to the power supply line 6. The source of the MOSFET 14 in the upper arm 8H and the drain of the MOSFET 14 in the lower arm 8L are connected to each other.

A freewheeling diode 15 is connected in reverse parallel to each MOSFET 14. The diode 15 may be the parasitic diode (body diode) of the MOSFET 14, or may be provided separately from the parasitic diode. The anode of the diode 15 is connected to the source of the corresponding MOSFET 14, and the cathode is connected to the drain.

The inverter 9 has the same configuration as the inverter 8. The inverter 9 includes upper and lower arm circuits 9HL for three phases. The upper and lower arm circuits 9HL include an upper arm 9H and a lower arm 9L. The upper arm 9H and the lower arm 9L are connected in series between the power supply lines 5 and 6, with the upper arm 9H positioned on the power supply line 5 side.

The connection node between the upper arm 9H and the lower arm 9L is connected, via an output line 16, to the winding of the corresponding phase in the rotating electric machine 3. The inverter 9 also has six arms. Each arm is configured with a switching element. The number of switching elements included in each arm is not particularly limited. There may be only one, or there may be multiple.

In the example shown in FIG. 1, n-channel type MOSFETs 17 are used as the switching elements included in each arm. In the upper arm 9H, the drain of the MOSFET 17 is connected to the power supply line 5. In the lower arm 9L, the source of the MOSFET 17 is connected to the power supply line 6. The source of the MOSFET 17 in the upper arm 9H and the drain of the MOSFET 17 in the lower arm 9L are connected to each other. A freewheeling diode 18 is connected in reverse parallel to each MOSFET 17.

As described above, the high potential side terminals (drain terminals) of the upper arms 8H and 9H of the inverters 8 and 9 are connected to the power supply line 5. The low potential side terminals (source terminals) of the lower arms 8L and 9L are connected to the power supply line 6. The node, which is the connection node between the upper arm 8H and the lower arm 8L, is connected to one end of the corresponding phase winding via the output line 13, and the node between the upper arm 9H and the lower arm 9L is connected to the other end of the corresponding phase winding via an output line 16. Specifically, one end of the U-phase winding 3U is connected to the node U1 of the U-phase upper and lower arm circuit 8HL, and the other end of the U-phase winding 3U is connected to the node U2 of the U-phase upper and lower arm circuit 9HL. One end of the V-phase winding 3V is connected to the node V1 of the V-phase upper and lower arm circuit 8HL, and the other end of the V-phase winding 3V is connected to the node V2 of the V-phase upper and lower arm circuit 9HL. One end of the W-phase winding 3W is connected to the node W1 of the W-phase upper and lower arm circuit 8HL, and the other end of the W-phase winding 3W is connected to the node W2 of the W-phase upper and lower arm circuit 9HL.

It should be noted that the switching elements included in the inverters 8 and 9 are not limited to the MOSFETs described above. For example, IGBTs may be used. IGBT is an abbreviation for Insulated Gate Bipolar Transistor. In the case of IGBTs as well, a freewheeling diode is connected in reverse parallel. The types of switching elements included in the inverters 8 and 9 may be the same or different. For example, one of the inverters 8 or 9 may be constituted by a MOSFET, and the other by an IGBT.

The switch 10 is provided on at least one of the power supply lines 5 or 6, between the connection node of the inverter 8 and the connection node of the inverter 9. When in the closed state, the switch 10 connects the high-potential side terminal of the upper arm 9H of the inverter 9 to the smoothing capacitor 7. When in the open state, the switch 10 disconnects the connection between the high-potential side terminal of the upper arm 9H and the smoothing capacitor 7. As the switch 10, for example, a semiconductor switch or a mechanical relay can be employed.

In the example shown in FIG. 1, a semiconductor switch, that is, a switching element formed on a semiconductor chip, is employed as the switch 10. The switching element is not particularly limited. The switching element may have a configuration common to at least one of the switching elements included in the inverter 8 or 9, or it may have a different configuration. In FIG. 1, the switching element included in the switch 10 is a MOSFET 19. A diode is connected in reverse parallel to the MOSFET 19. When the MOSFET 19 is turned on and the switch 10 is closed, the high-potential-side terminal of the upper arm 9H is electrically connected to the smoothing capacitor 7. When the MOSFET 19 is turned off and the switch 10 is in the open state, the electrical connection between the high-potential-side terminal of the upper arm 9H and the smoothing capacitor 7 is interrupted.

The control unit (CTR) 11 may be configured to include, for example, a processor, memory, and storage. The processor performs various processes by accessing the memory. The memory is a rewritable volatile storage medium. The memory may be, for example, RAM. RAM is an abbreviation for Random Access Memory. The storage may be, for example, a rewritable non-volatile storage medium. A program executed by the processor is stored in the storage. The program constructs multiple functional units by causing the processor to execute instructions. The processing executed by the control unit 11 may be implemented by software processing in which the processor executes the above-mentioned program, or by hardware processing using dedicated electronic circuits.

The control unit 11 may include a drive command generation unit (not shown) and a drive circuit unit. The drive command generation unit controls the inverters 8 and 9. The drive command generation unit generates drive commands (command signals) for controlling the on/off states of MOSFETs 14 and 17, and outputs them to the drive circuit unit. The drive command generation unit generates drive commands based on the drive requests for the rotating electric machine 3, such as the torque command value input from a higher-level ECU (not shown), as well as signals detected by various sensors.

The various sensors may include, for example, the current sensor 12 illustrated in FIG. 1, as well as a rotation angle sensor and a voltage sensor (not shown). The current sensor 12 detects the phase currents flowing through each phase winding 3U, 3V, and 3W. The rotation angle sensor detects the rotational angle of the rotor of the rotating electric machine 3. The voltage sensor detects the voltage across both terminals of the smoothing capacitor 7.

The drive command generation unit controls the switch 10. The drive command generation unit generates drive commands for controlling the on/off states of the MOSFET 19 that is included in the switch 10. This drive command is a switching command for toggling the open and closed states of the switch 10.

The drive circuit unit is sometimes referred to as a driver. The drive circuit unit can independently control the on/off states of six MOSFETs 14, six MOSFETs 17, and one MOSFET 19, respectively, based on the drive commands. The drive circuit unit outputs drive signals so that, for example, the drive voltage (gate voltage Vge) is increased during the ON period of a pulse-shaped drive command and decreased during the OFF period.

### (Star Connection Drive and Open Connection Drive)

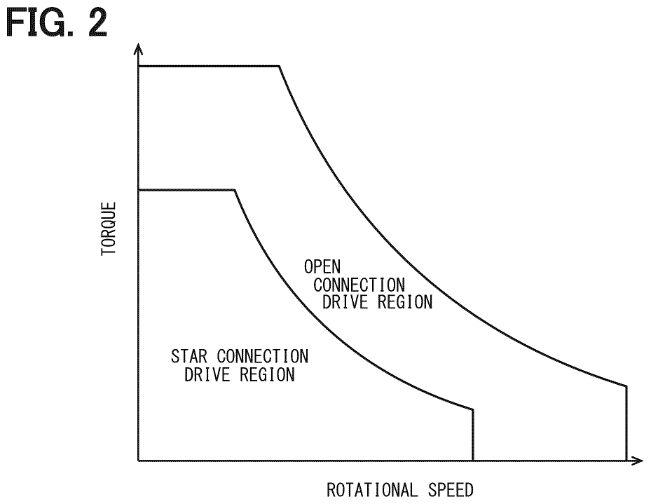

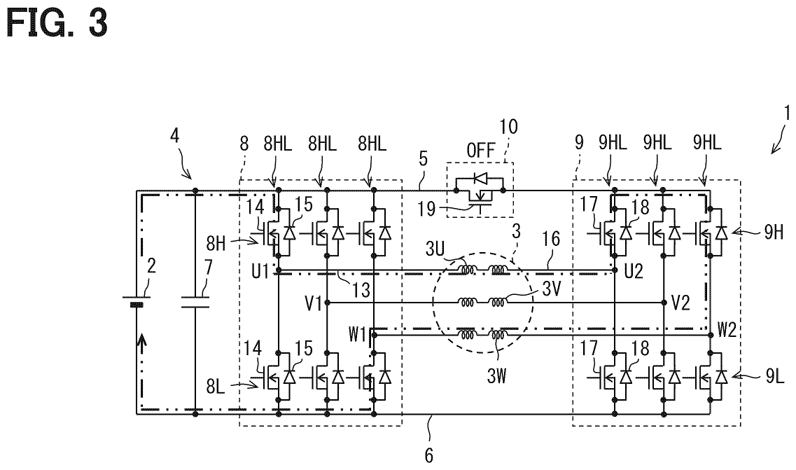

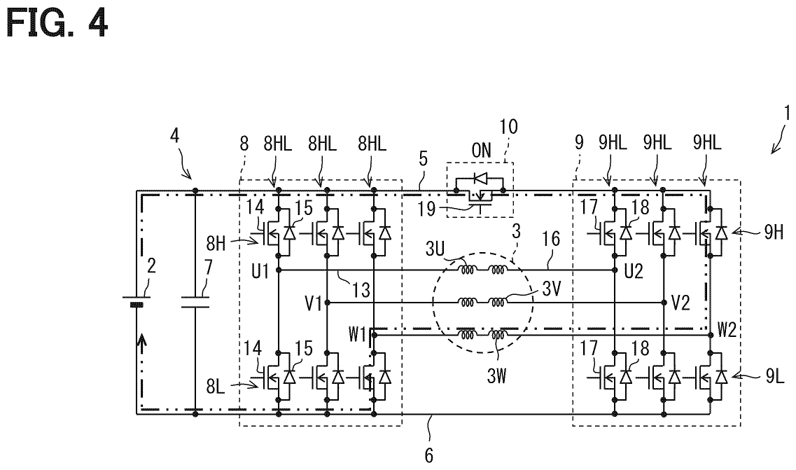

Next, star connection drive and open connection drive will be explained with reference to FIGS. 2, 3, and 4. FIG. 2 is an operation point map of the rotating electric machine 3, with rotational speed on the horizontal axis and torque on the vertical axis. FIG. 3 is a diagram illustrating star connection drive. FIG. 4 is a diagram illustrating open connection drive.

As shown in FIG. 2, the drive region of the rotating electric machine 3 is divided into two areas according to rotational speed and torque. One of the drive regions is the star connection drive region. The star connection drive region is the normal operating range. The other drive region is the open connection drive region. The open connection drive region is an area of higher speed or higher torque than the star connection drive region.

When the operating point is within the star connection drive region, the control unit 11 performs control for star connection drive. The star connection drive is sometimes referred to as Y drive. The control unit 11 controls the MOSFETs 14, 17, and 19 so that the windings 3U, 3V, and 3W are brought into a star connection state. Specifically, as shown in FIG. 3, the switch 10 is set to the open state, that is, the MOSFET 19 is turned off. Additionally, the inverter 9 is set to a neutral point configuration. As illustrated in FIG. 3, for example, the MOSFETs 17 of the upper arms 9H of all phases may be turned on, and the MOSFETs 17 of the lower arms 9L of all phases may be turned off. The MOSFETs 17 of the upper arms 9H of all phases may be turned off, and the MOSFETs 17 of the lower arms 9L of all phases may be turned on. Then, the MOSFETs 14 of the inverter 8 are controlled according to drive requests or the like.

The double-dashed arrows shown in FIG. 3 indicate an example of a current path. FIG. 3 shows the current path when the MOSFET 14 of the upper arm 8H of the U-phase and the MOSFET 14 of the lower arm 8L of the W-phase are turned on. In the example shown in FIG. 3, the upper arm 9H side of the inverter 9 is turned on, and the lower arm 9L side is turned off. The current flows in the following order: upper arm 8H of the U-phase→node U1→U-phase winding 3U→node U2→upper arm 9H of the U-phase→upper arm 9H of the W-phase→node W2→W-phase winding 3W→node W1→lower arm 8L of the W-phase. In this way, the current flows without passing through the switch 10.

The control method of the inverter 8 by the control unit 11 is not particularly limited. For example, a PWM control method or an overmodulation PWM control method may be used. In the PWM control method and the overmodulation PWM control method, the drive command generation unit outputs, for example, a triangular wave, a sawtooth wave, or a rectangular wave as a high-frequency carrier (carrier wave). Then, by comparing the sinusoidal voltage signal as a torque command value with the carrier, a pulse-shaped drive command is generated. For example, a rectangular wave control method may also be used. In the rectangular wave control method, the drive command generation unit generates, as a drive command, a rectangular wave pulse in which the ratio of the on and off periods is one to one within one control cycle, based on the sinusoidal voltage signal as the torque command value. For example, the control method may be switched according to the rotational speed of the rotating electric machine 3. The rectangular wave control has a higher voltage utilization rate than PWM control. Within the star connection drive region, a PWM control method may be used in the low to medium speed range, and the rectangular wave control method may be used in the high speed range.

When the operating point is in the open connection drive region, the control unit 11 executes control for open connection drive. The open connection drive is sometimes referred to as H drive. The control unit 11 sets the switch 10 to the closed state, that is, turns on the MOSFET 19, and disconnects the neutral point by means of the inverter 9. By disconnecting the neutral point, an open connection of the U-phase upper and lower arm circuits 8HL and 9HL via the U-phase winding 3U is formed. Similarly, an open connection of the V-phase upper and lower arm circuits 8HL and 9HL via the V-phase winding 3V is formed. An open connection of the W-phase upper and lower arm circuits 8HL and 9HL via the W-phase winding 3W is formed. The control unit 11 regards each phase as an independent open connection and controls the applied voltage for each phase individually. The control unit 11, in a common phase, turns on one of the upper arms 8H or 9H of the inverters 8 and 9, and the other of the lower arms 8L or 9L of the inverters 8 and 9.

The double-dashed arrows shown in FIG. 4 indicate an example of a current path. In FIG. 4, the current path is shown when the MOSFET 14 of the W-phase lower arm 8L and the MOSFET 17 of the W-phase upper arm 9H are turned on. The current flows in the order of: switch 10→W-phase upper arm 9H→node W2→W-phase winding 3W→node W1→W-phase lower arm 8L. In this manner, current flows via the switch 10.

The control method of the inverters 8 and 9 by the control unit 11 is not particularly limited. For example, a PWM control method may be used. A rectangular wave control method or an overmodulation PWM control method may also be used. The control method may be switched according to the rotational speed of the rotating electric machine 3. As described above, the control unit 11 is capable of independently controlling each of the six MOSFETs 14 and each of the six MOSFETs 17. Therefore, it is possible to allow current to flow in both the positive and negative directions for each of the phase windings 3U, 3V, and 3W. The positive direction refers to the direction in which current flows from the inverter 8 side to the inverter 9 side. The negative direction refers to the direction in which current flows from the inverter 9 side to the inverter 8 side.

For example, the two MOSFETs 17 included in the upper and lower arm circuit 9HL of the U-phase may be complementarily switched on and off by PWM control, while the MOSFET 14 of the upper arm 8H of the U-phase is turned off and the MOSFET 14 of the lower arm 8L of the U-phase is turned on. As a result, current flows in the negative direction through the U-phase winding 3U. On the other hand, the two MOSFETs 14 included in the upper and lower arm circuit 8HL of the U-phase may be complementarily switched on and off by PWM control, while the MOSFET 17 of the upper arm 9H of the U-phase is turned off and the MOSFET 17 of the lower arm 9L of the U-phase is turned on. As a result, current flows in the positive direction through the U-phase winding 3U.

As described above, the inverters 8 and 9 are capable of switching between star connection drive and open connection drive. By executing open connection drive instead of star connection drive, it is possible to output in a higher rotational speed range or a higher torque range.

### (Power Conversion Apparatus)

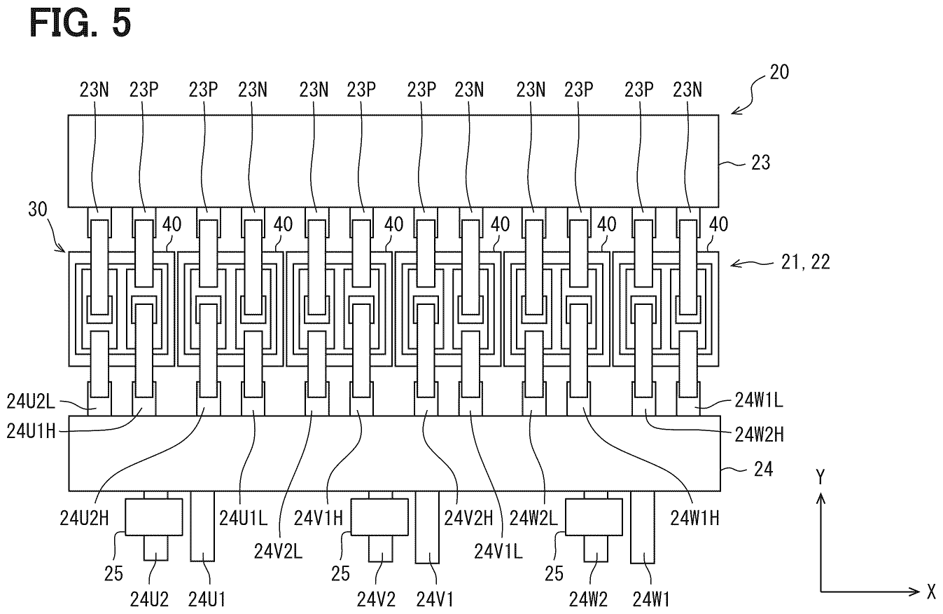

FIG. 5 is a diagram showing an example of a power conversion apparatus. For convenience, in FIG. 5, the elements covered by the encapsulating body included in the semiconductor device are shown as transparent. The power conversion apparatus provides at least a part of the power conversion circuit 4. The power conversion apparatus provides at least the inverters 8 and 9. The power conversion apparatus 20 illustrated in FIG. 5 is equipped with two inverters 21 and 22, a capacitor 23, an output terminal block 24, and a current sensor 25, among other components.

In the following description, the thickness direction of the substrate, which will be described later and is included in the semiconductor device, is defined as the Z-direction, and one direction orthogonal to the Z-direction is defined as the X-direction. The direction orthogonal to both the Z-direction and the X-direction is defined as the Y-direction. Unless otherwise specified, the shape viewed in plan from the Z-direction, in other words, the shape along the XY plane defined by the X and Y-directions, is referred to as the planar shape. In addition, a plan view in the Z-direction may simply be referred to as a plan view.

The inverters 21 and 22 correspond to the inverters 8 and 9. The inverter 21 provides the above-mentioned inverter 8, and the inverter 22 provides the inverter 9. The inverters 21 and 22 include a semiconductor module 30. The semiconductor module 30 includes at least one semiconductor device 40. In the example shown in FIG. 5, the inverters 21 and 22 are each configured by a semiconductor module 30 that includes six semiconductor devices 40. Details of the semiconductor module 30 and the semiconductor device 40 will be described later.

The capacitor 23 provides a smoothing capacitor 7. The capacitor 23 includes, for example, a case (not shown) and a capacitor element housed within the case. The capacitor element is, for example, a film capacitor element. The capacitor element is formed by winding a film around a predetermined axis. The capacitor element has electrodes (not shown) at both end faces of the axis. The electrode is sometimes referred to as “Metallikon.” The capacitor 23 is provided with a P busbar 23P connected to the positive electrode and an N busbar 23N connected to the negative electrode.

The P busbar 23P and the N busbar 23N are plate-shaped metal members. The P busbar 23P and the N busbar 23N are connected to the corresponding electrodes by means such as soldering, resistance welding, or laser welding. In FIG. 5, the terminal portions of the P busbar 23P and the N busbar 23N for connection to the semiconductor module 30 (semiconductor device 40) are illustrated. The P busbar 23P and the N busbar 23N have terminal portions (not shown) for electrically connecting the smoothing capacitor 7 and the DC power supply 2.

Although not shown in the drawings, the semiconductor switch that provides the switch 10 is, for example, integrally provided with the capacitor 23. The semiconductor switch is provided, for example, in the P busbar 23P, in the path that electrically connects the terminal portion connected to the inverter 21 and the terminal portion connected to the inverter 22. The semiconductor switch may also be provided, for example, in the N busbar 23N, in the path that electrically connects the terminal portion connected to the inverter 21 and the terminal portion connected to the inverter 22.

The output terminal block 24 electrically interconnects the inverters 21 and 22 with the rotating electric machine 3. The output terminal block 24 may also be referred to as a motor terminal block. The output terminal block 24 includes a case made of an electrically insulating material such as resin, and a busbar or the like held within the case. The busbar 24U1 provides the output line 13 connected to the node U1 of the inverter 8 (21). The busbar 24U2 provides the output line 16 connected to the node U2 of the inverter 9 (22). The busbar 24V1 provides the output line 13 connected to the node V1 of the inverter 8 (21). The busbar 24V2 provides the output line 16 connected to the node V2 of the inverter 9 (22). The busbar 24W1 provides the output line 13 connected to the node W1 of the inverter 8 (21). The busbar 24W2 provides the output line 16 connected to the node W2 of the inverter 9 (22).

The busbars 24U1H and 24U1L are electrically connected to the busbar 24U1. The busbars 24U1H and 24U1L may be continuously connected to the busbar 24U1, or may be joined by bonding. The busbar 24U1H is electrically connected to the upper arm 8H of the U-phase of inverter 8 (21), and the busbar 24U1L is electrically connected to the lower arm 8L of the U-phase. The busbars 24U2H and 24U2L are electrically connected to the busbar 24U2. The busbar 24U2H is electrically connected to the upper arm 9H of the U-phase of inverter 9 (22), and the busbar 24U2L is electrically connected to the lower arm 9L of the U-phase.

Similarly, the busbars 24V1H and 24V1L are electrically connected to the busbar 24V1. The busbar 24V1H is electrically connected to the upper arm 8H of the V-phase of the inverter 8 (21), and the busbar 24V1L is electrically connected to the lower arm 8L of the V-phase. The busbars 24V2H and 24V2L are electrically connected to the busbar 24V2. The busbar 24V2H is electrically connected to the upper arm 9H of the V-phase of inverter 9 (22), and the busbar 24V2L is electrically connected to the lower arm 9L of the V-phase.

The busbars 24W1H and 24W1L are electrically connected to the busbar 24W1. The busbar 24W1H is electrically connected to the upper arm 8H of the W-phase of inverter 8 (21), and the busbar 24W1L is electrically connected to the lower arm 8L of the W-phase. The busbars 24W2H and 24W2L are electrically connected to the busbar 24W2. The busbar 24W2H is electrically connected to the upper arm 9H of the W-phase of inverter 9 (22), and the busbar 24W2L is electrically connected to the lower arm 9L of the W-phase.

The current sensor 25 provides the current sensor 12. The current sensor 25 is disposed on the busbars 24U2, 24V2, and 24W2 of the output terminal block 24. The current sensor 25 individually detects the phase currents flowing through each of the busbars 24U2, 24V2, and 24W2. The current sensor 25 may be provided integrally with the output terminal block 24. The current sensor 25 may be disposed on the busbars 24U1, 24V1, and 24W1, or may be disposed on the busbars 24U1, 24V1, 24W 1, 24U2, 24V2, and 24W2.

In the above-described power conversion apparatus 20, the semiconductor module 30 is disposed, in the Y-direction, between the capacitor 23 and the output terminal block 24. The semiconductor devices 40 are arranged side by side in the X-direction.

The power conversion apparatus 20 may be provided with a case that houses the inverters 21 and 22, the capacitor 23, the output terminal block 24, and the current sensor 25. The power conversion apparatus 20 may be provided with a cooler for cooling the semiconductor module 30 and the like. The cooler may be configured such that a refrigerant flows through an internal flow path, or it may be a heat sink equipped with fins or the like. The cooler may be integrally provided with the case that houses the inverters 21 and 22. The power conversion apparatus 20 may be provided with an input terminal block that electrically connects the smoothing capacitor 7 (capacitor 23) and the DC power supply 2. The power conversion apparatus 20 may be provided with a circuit board that supplies the control unit 11.

### (Semiconductor Module and Semiconductor Device)

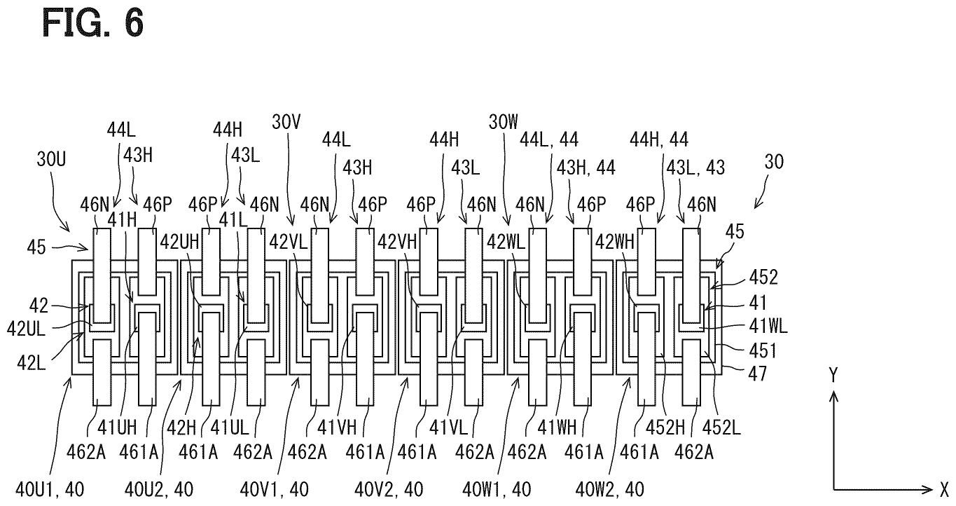

FIG. 6 is a plan view showing an example of the semiconductor module 30. FIG. 6 corresponds to FIG. 5. In FIG. 6, as in FIG. 5, elements covered by the encapsulating body are shown as transparent for illustrative purposes. As described above, the semiconductor module 30 provides two inverters 21 and 22 (8 and 9) that are connected to the common rotating electric machine 3. The semiconductor module 30 includes at least one semiconductor device 40.

In the example shown in FIG. 6, the semiconductor module 30 includes a U-phase semiconductor module 30U, a V-phase semiconductor module 30V, and a W-phase semiconductor module 30W. The semiconductor module 30U provides the U-phase for the inverters 21 and 22. The semiconductor module 30V provides the V-phase for the inverters 21 and 22. The semiconductor module 30W provides the W-phase for the inverters 21 and 22. The semiconductor modules 30U, 30V, and 30W are arranged in the X-direction. Each of the semiconductor modules 30U, 30V, and 30W includes two semiconductor devices 40. The semiconductor module 30 includes six semiconductor devices 40.

The semiconductor module 30U includes, as the semiconductor devices 40, a semiconductor device 40U1 and a semiconductor device 40U2. The semiconductor devices 40U1 and 40U2 are arranged side by side in the X-direction so as to be adjacent to each other. The semiconductor module 30V includes a semiconductor device 40V1 and a semiconductor device 40V2. The semiconductor devices 40V1 and 40V2 are arranged side by side in the X-direction so as to be adjacent to each other. The semiconductor module 30W includes a semiconductor device 40W1 and a semiconductor device 40W2. The semiconductor devices 40W1 and 40W2 are arranged side by side in the X-direction so as to be adjacent to each other.

The semiconductor module 30 includes semiconductor elements 41 and 42, and current paths 43 and 44. The semiconductor device 40 illustrated in FIG. 6 is provided, within a single semiconductor device 40, with the semiconductor elements 41 and 42, as well as the current paths 43 and 44. The semiconductor element 41 is included in the inverter 21 (8). The semiconductor element 42 is included in the inverter 22 (9). The current path 43 is included in the inverter 21. The current path 44 is included in the inverter 22.

The semiconductor elements 41 and 42 are formed by providing vertical-type elements on a semiconductor substrate made of materials such as silicon (Si) or wide bandgap semiconductors having a bandgap wider than that of silicon. Examples of wide bandgap semiconductors include silicon carbide (SiC), gallium nitride (GaN), gallium oxide (Ga₂O₃), and diamond. The semiconductor elements 41 and 42 may also be referred to as power devices or semiconductor chips.

The vertical-type elements are configured to allow the main current to flow in the thickness direction of the semiconductor elements 41 and 42 (semiconductor substrates). The semiconductor elements 41 and 42 are arranged so that their thickness direction is approximately parallel to the Z-direction. The semiconductor elements 41 and 42 have main electrodes on both surfaces in the thickness direction. In this embodiment, the semiconductor elements 41 and 42 are formed by providing n-channel MOSFETs as vertical-type elements on semiconductor substrates made of SiC. The semiconductor elements 41 and 42 have a drain electrode on the lower surface, which faces a substrate 45 described later, as the main electrode, and a source electrode on the upper surface opposite to the lower surface.

When the MOSFET is turned on, a current (main current) flows between the main electrodes, that is, between the drain electrode and the source electrode. In the case where the diode is a parasitic diode, the source electrode also serves as the anode electrode, and the drain electrode also serves as the cathode electrode. The diode may be configured on a separate chip from the MOSFET. The drain electrode is the main electrode on the high potential side, and the source electrode is the main electrode on the low potential side. The drain electrode is formed over almost the entire area of the lower surface. The source electrode is formed on a portion of the upper surface.

The semiconductor elements 41 and 42 have a substantially rectangular planar shape. The semiconductor elements 41 and 42 have pads, which are signal electrodes, on their upper surfaces. The pads are formed at positions on the upper surface different from those of the source electrodes. The pads include at least a gate pad.

The semiconductor element 41 includes a semiconductor element 41H that is included in the upper arm 8H and a semiconductor element 41L that is included in the lower arm 8L. The semiconductor element 42 includes a semiconductor element 42H that is included in the upper arm 9H and a semiconductor element 42L that is included in the lower arm 9L. The configurations of the semiconductor elements 41 and 42 may be the same as each other or may be different from each other. The semiconductor element 41H has semiconductor elements 41UH, 41VH, and 41WH. The semiconductor element 41L has semiconductor elements 41UL, 41VL, and 41WL. The semiconductor element 42H has semiconductor elements 42UH, 42VH, and 42WH. The semiconductor element 42L has semiconductor elements 42UL, 42VL, and 42WL. In the following, the semiconductor elements 41H, 41UH, 41VH, 41WH, 42H, 42UH, 42VH, and 42WH may be referred to as upper arm elements. The semiconductor elements 41L, 41UL, 41VL, 41WL, 42L, 42UL, 42VL, and 42WL may be referred to as lower arm elements.

The semiconductor elements 41 and 42 are arranged in the X-direction. The semiconductor elements 41 and 42 are alternately arranged in the X-direction. The semiconductor elements 41 and 42 are arranged such that elements whose ON period at least partially overlaps are positioned adjacent to each other. For example, in the U phase of the inverters 21 and 22, that is, the semiconductor module 30U, the semiconductor elements 41 and 42 are arranged in the following order from one end in the X-direction: the semiconductor element 42UL, the semiconductor element 41UH, the semiconductor element 42UH, and the semiconductor element 41UL. The semiconductor device 40U1 is provided with a semiconductor element 41UH and a semiconductor element 42UL. The semiconductor elements 41UH and 42UL are arranged side by side in the X-direction. The semiconductor device 40U2 is provided with the semiconductor element 41UL and the semiconductor element 42UH. The semiconductor elements 41UL and 42UH are arranged side by side in the X-direction. The semiconductor elements 41UH, 41UL, 42UH, and 42UL are arranged side by side in the X-direction so that the semiconductor elements 41UH and 42UH are adjacent to each other. The semiconductor devices 40U1 and 40U2 are arranged so that the semiconductor elements 41UH and 42UH are adjacent to each other.

The semiconductor elements 41 and 42 included in the V phase of the inverters 21 and 22, that is, the semiconductor module 30V, are arranged in the same manner as those of the U phase. The semiconductor elements 41 and 42 that are included in the semiconductor module 30V are arranged in the order of the semiconductor element 42VL, the semiconductor element 41VH, the semiconductor element 42VH, and the semiconductor element 41VL from one end side in the X-direction. The semiconductor element 42VL is arranged adjacent to the semiconductor element 41UL. The semiconductor device 40V1 includes the semiconductor element 41VH and the semiconductor element 42VL. The semiconductor elements 41VH and 42VL are arranged in the X-direction. The semiconductor device 40V2 includes the semiconductor element 41VL and the semiconductor element 42VH. The semiconductor elements 41VL and 42VH are arranged in the X-direction. The semiconductor elements 41VH, 41VL, 42VH, and 42VL are arranged in the X-direction such that the semiconductor elements 41VH and 42VH are adjacent to each other. The semiconductor devices 40V1 and 40V2 are arranged so that the semiconductor elements 41VH and 42VH are adjacent to each other.

The W-phase of the inverters 21 and 22, namely the semiconductor elements 41 and 42 included in the semiconductor module 30W, are arranged in the same manner as the U-phase. The semiconductor elements 41 and 42 included in the semiconductor module 30W are arranged, from one end in the X-direction, in the order of the semiconductor element 42WL, the semiconductor element 41WH, the semiconductor element 42WH, and the semiconductor element 41WL. The semiconductor element 42WL is arranged adjacent to the semiconductor element 41VL. The semiconductor device 40W1 includes a semiconductor element 41WH and a semiconductor element 42WL. The semiconductor elements 41WH and 42WL are arranged side by side in the X-direction. The semiconductor device 40W2 includes a semiconductor element 41WL and a semiconductor element 42WH. The semiconductor elements 41WL and 42WH are arranged side by side in the X-direction. The semiconductor elements 41WH, 41WL, 42WH, and 42WL are arranged side by side in the X-direction such that the semiconductor elements 41WH and 42WH are adjacent to each other. The semiconductor devices 40W1 and 40W2 are arranged such that the semiconductor elements 41WH and 42WH are adjacent to each other.

The current path 43 includes a current path 43H having the semiconductor element 41H, and a current path 43L having the semiconductor element 41L. The current path 44 includes a current path 44H having the semiconductor element 42H, and a current path 44L having the semiconductor element 42L. The semiconductor module 30 has three current paths 43H corresponding to the semiconductor elements 41UH, 41VH, and 41WH. The semiconductor module 30 has three current paths 43L corresponding to the semiconductor elements 41UL, 41VL, and 41WL. The semiconductor module 30 has three current paths 44H corresponding to the semiconductor elements 42UH, 42VH, and 42WH. The semiconductor module 30 has three current paths 44L corresponding to the semiconductor elements 42UL, 42VL, and 42WL. The current paths 43 and 44 are arranged in the X-direction corresponding to the arrangement of the semiconductor elements 41 and 42.

The current paths 43 and 44 may include, for example, the substrate 45 and an external connection terminal 46. The substrate 45 is arranged on the drain electrode side of the semiconductor elements 41 and 42. The substrate 45 is provided, for example, for each semiconductor device 40 unit. The substrate 45 has an insulating base material 451 and a wiring 452 disposed on one surface of the insulating base material 451. The insulating base material 451 is formed using an electrically insulating material such as ceramic or resin. The substrate 45 may have a metal body disposed on the surface opposite to said one surface in the Z-direction.

The wiring 452 is formed from a metal with good electrical and thermal conductivity, such as Cu or Al. The wiring 452 may have a plating film such as Ni-based or Au on its surface. In the example shown in FIG. 6, the substrate 45 has wirings 452H and 452L as the wiring 452. A single semiconductor element 42 is mounted on each wiring 452. The wiring 452H is included in the current paths 43H and 44H on the upper arm side. The upper arm element 41H or the upper arm element 42H is disposed on the wiring 452H. The drain electrode of the upper arm element 41H or the upper arm element 42H is joined to the wiring 452H. The wiring 452L is included in the current paths 43L and 44H on the lower arm side. A lower arm element 41L or a lower arm element 42L is disposed on the wiring 452L. The drain electrode of the lower arm element 41L or the lower arm element 42L is joined to the wiring 452L.

The wirings 452H and 452L extend in the Y-direction. In a single semiconductor device 40, the wirings 452H and 452L are arranged side by side in the X-direction, which is perpendicular to the direction in which they extend. The wirings 452H and 452L run in parallel. The wiring 452H and the wiring 452L are arranged facing each other. In two adjacent semiconductor devices 40, the wirings 452H of each device or the wirings 452L of each device run in parallel with each other.

The external connection terminal 46 is a terminal for electrically connecting the semiconductor module 30 (semiconductor device 40) to an external device. The external connection terminal 46 is formed using a metal material with good conductivity, such as copper. The external connection terminal 46 is, for example, a plate material. The external connection terminal 46 includes output terminals 461A and 462A, a P terminal 46P, and an N terminal 46N as main terminals that are electrically connected to the main electrodes of the semiconductor elements 41 and 42.

The output terminals 461A and 462A may also be referred to as AC terminals or O terminals. The output terminals 461A and 462A are electrically connected, via the output terminal block 24, to the windings 3U, 3V, and 3W of the corresponding phases of the rotating electric machine 3. The output terminals 461A and 462A are provided for each of the current paths 43 and 44. In the example shown in FIG. 6, one output terminal 461A is provided for each of the current paths 43H and 44H, and one output terminal 462A is provided for each of the current paths 43L and 44L. Each semiconductor device 40 is provided with one output terminal 461A and one output terminal 462A. The output terminals 461A and 462A extend in the Y-direction. The output terminals 461A and 462A are arranged side by side in the X-direction. The output terminal 461A and the output terminal 462A are arranged facing each other. In the current paths 43H and 44H, the output terminal 461A is connected to the source electrode of the upper arm element. In the current paths 43L and 44L, the output terminal 462A is connected to the wiring 452L.

For example, the upper arm side output terminal 461A of the semiconductor device 40U1 is connected to the busbar 24U1H of the output terminal block 24, and the lower arm side output terminal 462A is connected to the busbar 24U2L. The upper arm side output terminal 461A of the semiconductor device 40U2 is connected to the busbar 24U2H, and the lower arm side output terminal 462A is connected to the busbar 24U1L. Similarly, the upper arm side output terminal 461A of the semiconductor device 40V1 is connected to the busbar 24V1H of the output terminal block 24, and the lower arm side output terminal 462A is connected to the busbar 24V2L. The upper arm side output terminal 461A of the semiconductor device 40V2 is connected to the busbar 24V2H, and the lower arm side output terminal 462A is connected to the busbar 24V1L. The upper arm side output terminal 461A of the semiconductor device 40W1 is connected to the busbar 24W1H of the output terminal block 24, and the lower arm side output terminal 462A is connected to the busbar 24W2L. The upper arm side output terminal 461A of the semiconductor device 40W2 is connected to the busbar 24W2H, and the lower arm side output terminal 462A is connected to the busbar 24W1L.

The P terminal 46P may also be referred to as a positive electrode terminal or a high potential power supply terminal. The P terminal 46P is electrically connected to the P busbar 23P of the capacitor 23. The N terminal 46N may also be referred to as a negative electrode terminal or a low potential power supply terminal. The N terminal 46N is electrically connected to the N busbar 23N of the capacitor 23. The P terminal 46P is provided for each of the current paths 43H and 44H. The N terminal 46N is provided for each of the current paths 43L and 44L. In the example shown in FIG. 6, one P terminal 46P is provided for each of the current paths 43H and 44H, and one N terminal 46N is provided for each of the current paths 43L and 44L. Each semiconductor device 40 is provided with one P terminal 46P and one N terminal 46N. In the semiconductor device 40, the P terminal 46P and the N terminal 46N extend in the Y-direction. The P terminal 46P and the N terminal 46N are arranged side by side in the X-direction. The P terminal 46P and the N terminal 46N are disposed facing each other.

In addition to the above-mentioned main terminals, the external connection terminal 46 is provided with a signal terminal (not shown). The signal terminal is electrically connected to the pads of the semiconductor elements 41 and 42. The signal terminal electrically connects, for example, the pad and a circuit board that provides the control unit 11. The signal terminal includes at least a terminal for applying a drive voltage to the gate electrodes of the semiconductor elements 41 and 42.

As illustrated in FIG. 6, the semiconductor device 40 may be provided with an encapsulant 47. The encapsulant 47 encapsulates the elements of the semiconductor device 40. The encapsulant 47 integrally encapsulates the semiconductor elements 41 and 42, the substrate 45, and portions of each of the external connection terminals 46. In the example shown in FIG. 6, the encapsulant 47 has an approximately rectangular planar shape. Among the external connection terminals 46, the output terminals 461A and 462A protrude to the outside from one of the side surfaces of the encapsulant 47. The P terminal 46P and the N terminal 46N protrude to the outside from the side surface opposite to the output terminals 461A and 462A in the Y-direction.

In a configuration in which the substrate 45 is disposed on the case or cooler of the power conversion apparatus 20, the encapsulant 47 may be, for example, a gel or a potting resin. The encapsulant 47 may also be a resin molded body. The encapsulant 47 may be provided for each semiconductor device 40, as illustrated in FIG. 6, or may be provided for each semiconductor module 30U, 30V, 30W. The encapsulant 47 may be integrally provided in the semiconductor module 30.

In the semiconductor module 30 having the above configuration, the current paths 43 and 44 are arranged alternately. Each of the current paths 43 and 44 extends in the Y-direction. The current paths 43 and 44 provided in a single semiconductor device 40 are arranged side by side in the X-direction. The current paths 43 and 44L run parallel to each other. The current paths 43 and 44 are arranged facing each other. In two adjacent semiconductor devices 40, either the upper arm side current paths 43H and 44H or the lower arm side current paths 43L and 44L run parallel to each other.

In FIG. 6, in each of the semiconductor devices 40U1, 40V1, and 40W1, the current paths 43H and 44L run parallel to each other. In each of the semiconductor devices 40U2, 40V2, and 40W2, the current paths 43L and 44H run parallel to each other. In the adjacent semiconductor devices 40U1 and 40U2, the current paths 43H and 44H run parallel to each other. In the adjacent semiconductor devices 40V1 and 40V2, the current paths 43H and 44H run parallel to each other. In the adjacent semiconductor devices 40W1 and 40W2, the current paths 43H and 44H run parallel to each other. In the adjacent semiconductor devices 40U2 and 40V1, the current paths 43L and 44L run parallel to each other. In the adjacent semiconductor devices 40V2 and 40W1, the current paths 43L and 44L run parallel to each other.

The semiconductor module 30 is not limited to the configuration illustrated in FIG. 6. The semiconductor module 30 that provides the inverters 21 and 22 only needs to be equipped with at least one semiconductor device 40, as described above. The semiconductor device 40 is not limited to a configuration that includes only one of each semiconductor element 41 and 42.

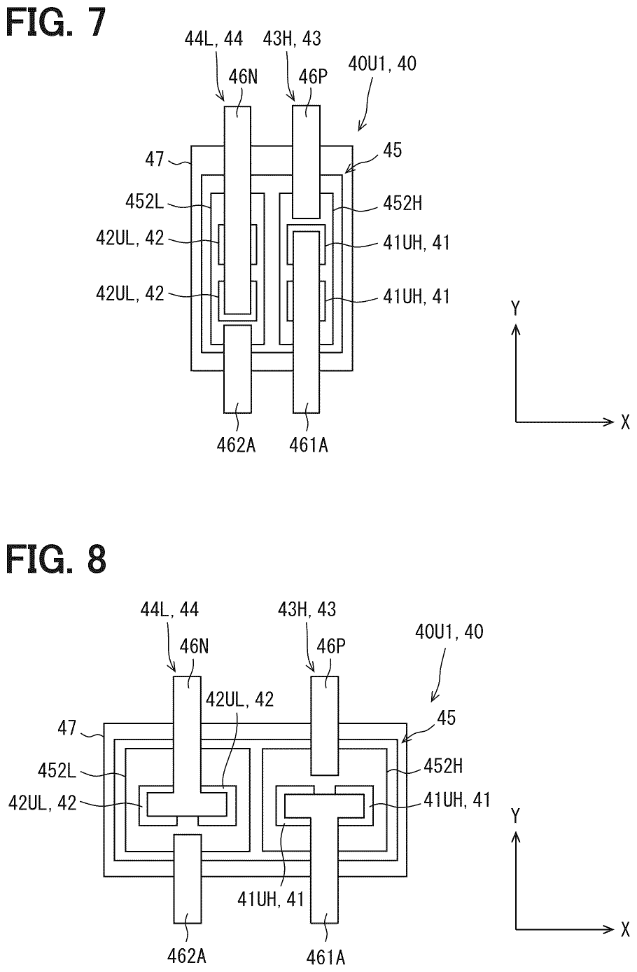

For example, as shown in FIG. 7, the semiconductor device 40U1 may be provided with two semiconductor elements 41UH that are included in the U-phase upper arm of the inverter 21 as the semiconductor elements 41 and 42, and two semiconductor elements 42UL that are included in the U-phase lower arm of the inverter 22. The two semiconductor elements 41UH are arranged on the wiring 452H extending in the Y-direction. The semiconductor elements 41UH are arranged side by side in the Y-direction. The output terminal 461A is connected to the source electrodes of the two semiconductor elements 41UH. The two semiconductor elements 41UH are connected in parallel with each other.

Similarly, the two semiconductor elements 42UL are arranged on the wiring 452L extending in the Y-direction. The semiconductor elements 42UL are arranged side by side in the Y-direction. The N terminal 46N is connected to the source electrodes of the two semiconductor elements 42UL. The two semiconductor elements 42UL are connected in parallel with each other. One of the semiconductor elements 41UH and one of the semiconductor elements 42UL are aligned in the X-direction, and the other one of the semiconductor elements 41UH and the other one of the semiconductor elements 42UL are also aligned in the X-direction. The group of semiconductor elements 41UH and the group of semiconductor elements 42UL are arranged side by side in the X-direction. The current path 43H and the current path 43L are arranged side by side and run parallel to each other in the X-direction.

The number of semiconductor elements 41 and 42 connected in parallel is not limited to the example shown in FIG. 7 (two semiconductor elements). Three or more semiconductor elements may also be provided. In FIG. 7, an example is shown in which the semiconductor elements 41 and 42 connected in parallel are arranged side by side in the Y-direction; however, this is not limited thereto. For example, as shown in FIG. 8, it is also possible to adopt a configuration in which two semiconductor elements 41UH are arranged side by side in the X-direction and two semiconductor elements 42UL are arranged side by side in the X-direction. The four semiconductor elements 41 and 42 are arranged in a single row, with one of the semiconductor elements 41UH positioned adjacent to one of the semiconductor elements 42UL. The group of semiconductor elements 41UH and the group of semiconductor elements 42UL are arranged side by side in the X-direction. The current path 43H and the current path 43L are arranged side by side and run parallel to each other in the X-direction. Other semiconductor devices 40 included in the semiconductor module 30 may have the same configuration as the semiconductor device 40U1 shown in FIG. 7 or FIG. 8.

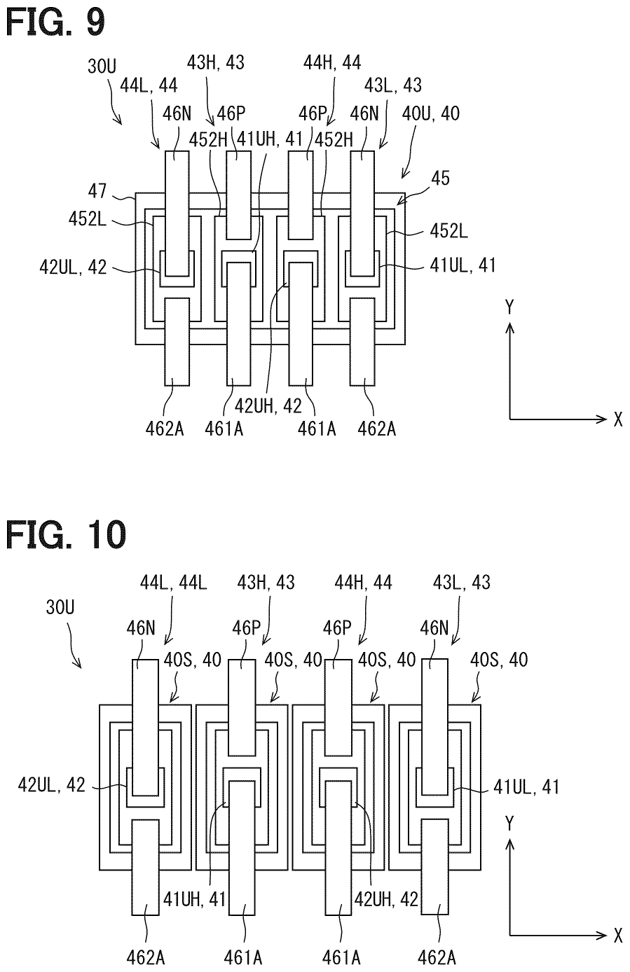

The semiconductor device 40 is not limited to a configuration that provides two arms among the twelve arms of the inverters 21, 22 (8, 9). For example, as shown in FIG. 9, the semiconductor device 40U may provide four arms that are included in the semiconductor module 30U. The semiconductor device 40U has a structure in which the above-mentioned two semiconductor devices 40U1 and 40U2 are integrated. The semiconductor device 40U is provided with the semiconductor elements 41UH, 41UL, 42UH, and 42UL. The semiconductor device 40U is provided with two output terminals 461A, two output terminals 462A, two P terminals 46P, and two N terminals 46N. In the example shown in FIG. 9, a single substrate 45 is provided with two wirings 452H and two wirings 452L. The semiconductor device 40U is provided with one current path each: 43H, 43L, 44H, and 44L.

The semiconductor elements 41UH, 41UL, 42UH, and 42UL are arranged in the X-direction. In the X-direction, the semiconductor elements are arranged in the order of 42UL, 41UH, 42UH, and 41UL. The semiconductor element 42UL is disposed next to the semiconductor element 41UH. The semiconductor element 41UL is disposed next to the semiconductor element 42UH. The semiconductor element 41UH is disposed next to the semiconductor element 42UH. The current path 43H and the current path 44L are arranged side by side and run parallel to each other in the X-direction. The current path 43L and the current path 44H are arranged side by side and run parallel to each other in the X-direction. The current path 43H and the current path 44H are arranged side by side and run parallel to each other in the X-direction. The semiconductor devices 40 of the other phases included in the semiconductor module 30 may have the same configuration as the semiconductor device 40U shown in FIG. 9.

For example, as shown in FIG. 10, a single semiconductor device 40S may provide a single arm. The four semiconductor devices 40S exemplified in FIG. 10 are included in the semiconductor module 30U. One of the semiconductor devices 40S is provided with the semiconductor element 41UH and the current path 43H. The other one of the semiconductor devices 40S is provided with the semiconductor element 41UL and the current path 43L. Another one of the semiconductor devices 40S is provided with the semiconductor element 42UH and the current path 44H. The other one of the semiconductor devices 40S is provided with the semiconductor element 42UL and the current path 44L.

The semiconductor elements 41UH, 41UL, 42UH, and 42UL are arranged in the X-direction. In the X-direction, the semiconductor elements are arranged in the order of 42UL, 41UH, 42UH, and 41UL. The semiconductor element 42UL is disposed next to the semiconductor element 41UH. The semiconductor element 41UL is disposed next to the semiconductor element 42UH. The semiconductor element 42UH is disposed next to the semiconductor element 41UH. The current path 43H and the current path 44L are arranged side by side and run parallel to each other in the X-direction. The current path 43L and the current path 44H are arranged side by side and run parallel to each other in the X-direction. The current path 43H and the current path 44H are arranged side by side and run parallel to each other in the X-direction. The other semiconductor devices 40 included in the semiconductor module 30 may have the same configuration as the semiconductor device 40S shown in FIG. 10. In other words, the semiconductor module 30 may include twelve semiconductor devices 40S.

Although not shown in the drawings, the semiconductor module 30 may include only one semiconductor device 40. The semiconductor device 40 may, for example, have a structure in which the above-mentioned six semiconductor devices 40U1, 40U2, 40V1, 40V2, 40W1, and 40W2 are integrated. It should be noted that FIGS. 7 to 10 show alternative examples of the semiconductor device 40. FIGS. 7 to 10 correspond to FIG. 6. In FIGS. 7 to 10 as well, elements covered by the encapsulant 47 are illustrated as transparent.

### (Magnetic Flux Cancellation During Open Connection Drive)

During open connection drive (H drive), in the common phase of the inverters 21 and 22 (8 and 9), the upper arm of one inverter and the lower arm of the other inverter are turned on. In the semiconductor module 30 described above, in the common phase, the upper arm element of one of the inverters 21 and 22 and the lower arm element of the other of the inverters 21 and 22 are arranged side by side. The current path 43H including the upper arm element and the current path 44L including the lower arm element run in parallel. Or alternatively, the current path 44H including the upper arm element and the current path 43L including the lower arm element run in parallel.

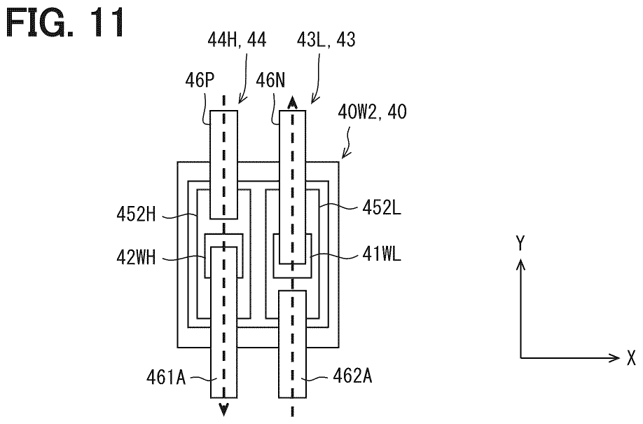

FIG. 11 shows the semiconductor device 40W2 having the configuration illustrated in FIG. 6. In FIG. 11, as exemplified in FIG. 4, the current flowing at the period when both the lower arm 8L of the W phase and the upper arm 9H of the W phase are turned on, that is, when both semiconductor elements 41WL and 42WH are turned on, is indicated by dashed arrows. In the semiconductor device 40W2, the semiconductor element 42WH is arranged adjacent to the semiconductor element 41WL. The current paths 43L and 44H run in parallel. The current flowing through the current path 43H, which includes the semiconductor element 42WH, and the current flowing through the current path 43L, which includes the semiconductor element 41WL, are in opposite directions and face each other, as indicated by the dashed arrows. Therefore, by canceling out the magnetic flux, the inductance can be reduced.

The same applies to the other semiconductor devices 40U1, 40U2, 40V1, 40V2, and 40W1. The same also applies to the configuration shown in other examples such as FIG. 10.

### (Magnetic Flux Cancellation During Y Drive)

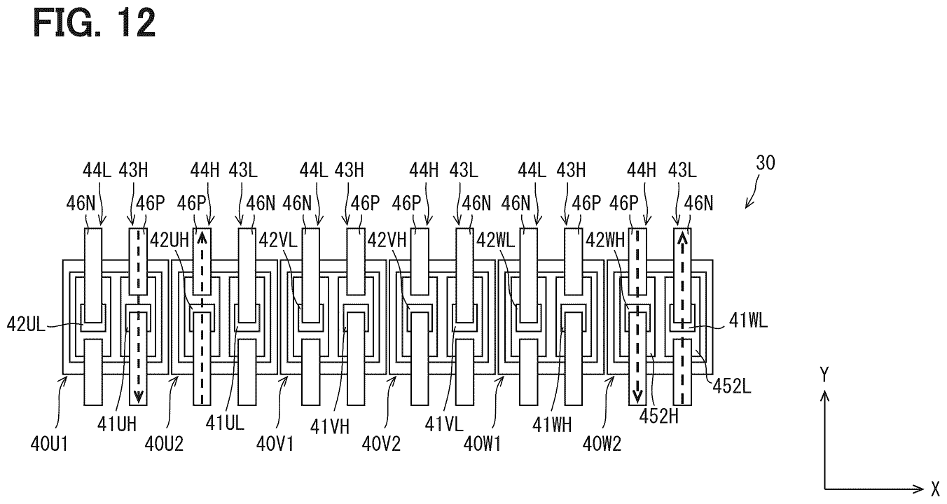

During star connection drive (Y drive), the inverter 9 (22) is set to the neutral point, and the inverter 8 (21) is controlled according to drive requirements and other factors. FIG. 12 shows the semiconductor module 30 having the configuration illustrated in FIG. 6. In FIG. 12, as exemplified in FIG. 3, all upper arms 9H of the inverter 9 are turned on to set the neutral point, and the current flowing at the period when both the upper arm 8H of the U phase and the lower arm 8L of the W phase of the inverter 8 are turned on is indicated by dashed arrows. In other words, the diagram shows the current that flows when the semiconductor elements 42UH, 42VH, and 42WH are turned on to set the inverter 22 to the neutral point, and the semiconductor elements 41UH and 41WL are turned on.

In the X-direction, the semiconductor device 40U1 is arranged adjacent to the semiconductor device 40U2. The semiconductor element 41UH is arranged adjacent to the semiconductor element 42UH in the X-direction. The current path 43H, which includes the semiconductor element 41UH, and the current path 44H, which includes the semiconductor element 42UH, run in parallel. The current flowing through the current path 43H, which includes semiconductor element 41UH, and the current flowing through the current path 44H, which includes semiconductor element 42UH, are opposite in direction and face each other, as indicated by the dashed arrows. Therefore, by canceling out the magnetic flux, the inductance can be reduced.

In the semiconductor device 40W2, the semiconductor element 42WH is arranged adjacent to the semiconductor element 41WL. The current paths 43L and 44H run in parallel. The current flowing through the current path 44H, which includes the semiconductor element 42WH, and the current flowing through the current path 43L, which includes the semiconductor element 41WL, are opposite in direction and face each other, as indicated by the dashed arrows. Therefore, by canceling out the magnetic flux, the inductance can be reduced. The same also applies to the configuration shown in other examples such as FIG. 10.

### (Summary of the First Embodiment)

The power conversion apparatus 20 of the present embodiment, as described above, includes two inverters 21 and 22 (8 and 9) that are connected to a common rotating electric machine 3. The inverters 21 and 22 include the semiconductor module 30. The semiconductor module 30 includes the semiconductor elements 41 and 42 and current paths 43 and 44. In the X-direction, adjacent to the semiconductor element 41 included in the inverter 21, there is a semiconductor element 42 included in the inverter 22, positioned such that at least a part of its ON period overlaps with the ON period of the semiconductor element 41. In addition, the current path 43 including the semiconductor element 41 and the current path 44 including the semiconductor element 42 run parallel to each other in the X-direction, arranged side by side, such that the currents flowing through them are in opposite directions and face each other.

With the above arrangement, when both adjacent semiconductor elements 41 and 42 are ON, the current flowing through the current path 43 and the current flowing through the current path 44 flow in opposite directions, facing each other. Therefore, by canceling out the magnetic flux, the inductance can be reduced. It should be noted that the inverter 21 (8) corresponds to the first inverter, and the inverter 22 (9) corresponds to the second inverter. The semiconductor element 41 corresponds to a first semiconductor element, and the semiconductor element 42 corresponds to a second semiconductor element. The current path 43 corresponds to a current path, and the current path 44 corresponds to a second current path. The X-direction corresponds to a predetermined direction.

The semiconductor element 41 may be included in a predetermined phase of the inverter 21, and the semiconductor element 42 may be included in a predetermined phase of the inverter 22. In other words, the adjacent semiconductor elements 41 and 42 may be included in a common phase in the inverters 21 and 22, for example, both may be included in the U phase. When both semiconductor elements 41 and 42 are turned on and current flows through the common phase of inverters 21 and 22, the current flowing through the current path 43 and the current flowing through the current path 44 are in opposite directions, facing each other. Therefore, by canceling out the magnetic flux, the inductance can be reduced.

The inverter 21 may be connected to one end of the windings 3U, 3V, and 3W of the rotating electric machine 3, and the inverter 22 may be connected to the other end of the windings 3U, 3V, and 3W. The inverters 21 and 22 may be switchable between star connection drive, in which the inverter 22 serves as a neutral point, and open connection drive, in which the neutral point provided by inverter 22 is disconnected and the voltage applied to each of the windings 3U, 3V, and 3W is controlled individually by phase. In such a configuration, during star connection drive, current flows through the common phase of the inverters 21 and 22. Further, during open connection drive, current also flows through the common phase of the inverters 21 and 22. As described above, by arranging the semiconductor elements 41 and 42 that are included in the common phase adjacent to each other, inductance can be reduced by canceling magnetic flux.

One of the semiconductor elements 41, 42 may be used as an upper arm element, and the other of the semiconductor elements 41, 42 may be used as a lower arm element. In open connection drive, in the common phase, the upper arm of one of the inverters 21, 22 and the lower arm of the other of the inverters 21, 22 are turned on. By configuring the adjacent semiconductor elements 41 and 42 as a combination of the semiconductor element 41H and the semiconductor element 42L and/or the semiconductor element 41L and the semiconductor element 42H, both semiconductor elements 41 and 42 are turned on during open connection drive. Therefore, by canceling out the magnetic flux, the inductance can be reduced.

The semiconductor module 30 may include at least one semiconductor device 40 having the semiconductor elements 41 and 42, the P terminal 46P, the N terminal 46N, and the output terminals 461A and 462A. One of the current paths 43 and 44 may have the P terminal 46P, the upper arm element, and the output terminal 461A, and the other of the current paths 43 and 44 may have the N terminal 46N, the lower arm element, and the output terminal 462A. Accordingly, within a single semiconductor device, during open connection drive, currents flow in opposite directions through current paths 43 and 44, facing each other. Therefore, by canceling out the magnetic flux, the inductance can be reduced. Since the single semiconductor device 40 includes the semiconductor elements 41 and 42 and the adjacent current paths 43 and 44, it is possible to reduce the overall size. As a result, the effect of magnetic flux cancellation is enhanced, and inductance can be further reduced. It should be noted that the output terminal 461A corresponds to a first output terminal, and the output terminal 462A corresponds to a second output terminal.

The semiconductor module 30 may include two semiconductor devices 40 that are included in the common phase of the inverters 21 and 22. One of the semiconductor devices 40 includes the semiconductor elements 41H and 42L, as well as the current paths 43H and 44L. The other semiconductor device 40 includes the semiconductor elements 41L and 42H, as well as the current paths 43L and 44H. The two semiconductor devices 40 may be configured such that the current flowing through one current path 43 of one semiconductor device 40 and the current flowing through another current path 44 of the other semiconductor device 40 flow in opposite directions, facing each other. During the star connection drive, the currents flowing through the adjacent current paths 43 and 44 of the two semiconductor devices 40 flow in opposite directions, facing each other. As described above, during the open connection drive, the currents flowing through the adjacent current paths 43 and 44 within each semiconductor device are oriented in opposite directions and face each other. Therefore, in both star connection drive and open connection drive, inductance can be reduced by flux cancellation.

The semiconductor module 30 may include, for example, the semiconductor devices 40U1 and 40U2. The semiconductor device 40U1 includes the semiconductor elements 41UH and 42UL, as well as the current paths 43H and 44L. The semiconductor device 40U2 includes the semiconductor elements 41UL and 42UH, as well as the current paths 43L and 44H. The semiconductor devices 40U1 and 40U2 are arranged such that the current flowing through one current path 43 of the semiconductor devices 40U1 and 40U2, and the current flowing through the other current path 44 of the semiconductor devices 40U1 and 40U2, are oriented in opposite directions and face each other. During the star connection drive, the currents flowing through the adjacent current paths 43 and 44 of the two semiconductor devices 40U1 and 40U2 are in opposite directions and face each other. Therefore, by canceling out the magnetic flux, the inductance can be reduced. The same applies to the semiconductor devices 40V1 and 40V2, as well as the semiconductor devices 40W1 and 40W2.

The two semiconductor devices 40 that are included in the common phase of the inverters 21 and 22 may be arranged side by side in the X-direction so that either the upper arm elements 41H and 42H or the lower arm elements 41L and 42L are adjacent to each other in the X-direction. For example, by arranging them on a common plane such as a case or a cooler, the two semiconductor devices 40 satisfy the predetermined positional relationship, so that the currents flowing in the adjacent current paths 43 and 44 of the two semiconductor devices 40 are in opposite directions and face each other. Therefore, with a simple configuration, the inductance can be reduced by canceling magnetic flux.

The semiconductor elements 41 and 42 that are adjacent in the X-direction may both be the upper arm elements 41H and 42H, or may both be the lower arm elements 41L and 42L. During the star connection drive, the currents flowing through the adjacent current paths 43 and 44 of the two semiconductor devices 40 flow in opposite directions, facing each other. Therefore, by canceling out the magnetic flux, the inductance can be reduced. Although not shown in the figures, a single semiconductor device 40 may include the upper arm elements 41H and 42H as the adjacent semiconductor elements 41 and 42, thereby included in the common phase of the inverters 21 and 22. The semiconductor device 40 may include the lower arm elements 41L and 42L that are included in the common phase of the inverters 21 and 22.

The semiconductor elements 41 and 42 in which MOSFETs are located on a SiC substrate may also be used. With the above configuration, inductance can be reduced, and consequently, switching surge can also be minimized. As a result, for example, switching speed can be increased. In addition, it is possible to suppress an increase in the number of elements.

### Second Embodiment

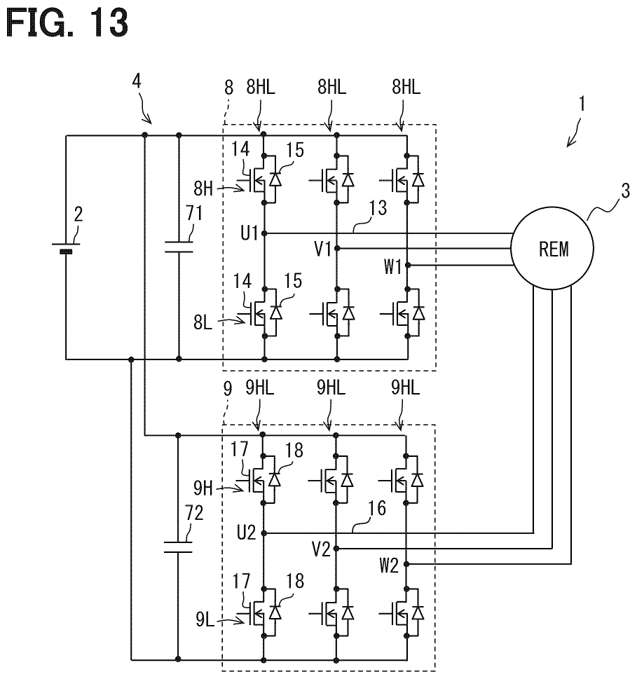

The present embodiment is a modification of the preceding embodiment as a basic configuration and may incorporate description of the preceding embodiment. In the preceding embodiment, an example was shown in which two inverters are connected to an open-winding type rotating electric machine. Alternatively, the two inverters are connected to a star-connected type rotating electric machine. FIG. 13 shows the drive system 1 and the power conversion circuit 4 according to the present embodiment. FIG. 13 illustrates the circuit configuration of the power conversion circuit 4. Similar to the preceding embodiment, the drive system 1 includes the DC power supply 2, the rotating electric machine 3, and the power conversion circuit 4. The rotating electric machine (REM) 3 is a star-connected type rotating electric machine. The rotating electric machine 3 is equipped with, for example, 2×3-phase windings. In the example shown in FIG. 13, the rotating electric machine 3 includes six-phase windings: U1, V1, W1, U2, V2, and W2. The windings U2, V2, and W2 are wound so that no phase difference occurs with respect to the corresponding windings U1, V1, and W1.

The power conversion circuit 4, like in the preceding embodiment, includes two inverters 8 and 9. The inverter 8 drives the three-phase rotating electric machine, while the inverter 9 drives the remaining three-phase rotating electric machine. Node U1 of the inverter 8 is connected to the U1-phase winding, node V1 is connected to the V1-phase winding, and node W1 is connected to the W1-phase winding. Node U2 of the inverter 9 is connected to the U2-phase winding, node V2 is connected to the V2-phase winding, and node W2 is connected to the W2-phase winding.

The power conversion circuit 4 includes a smoothing capacitor 71 and a smoothing capacitor 72. The smoothing capacitor 71 is provided between the DC power supply 2 and the inverter 8. The smoothing capacitor 71 is connected in parallel with the inverter 8. The smoothing capacitor 72 is provided between the DC power supply 2 and the inverter 9. The smoothing capacitor 72 is connected in parallel with the inverter 9.

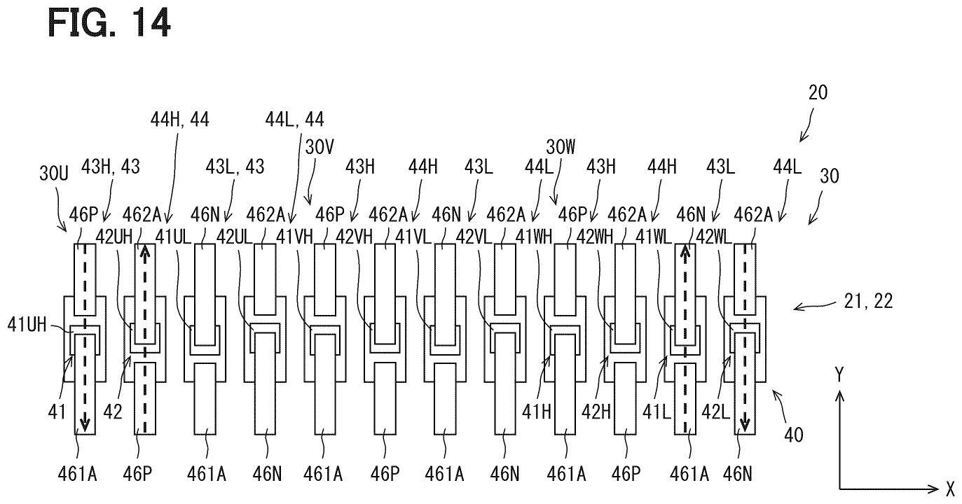

FIG. 14 illustrates an example of the power conversion apparatus 20 and the semiconductor module 30. The power conversion apparatus 20 includes at least the semiconductor modules 30 that are included in the inverters 21 and 22, similarly to the preceding embodiment. The semiconductor module 30 includes at least one semiconductor device 40. The configuration of the semiconductor device 40 is the same as in the preceding embodiment. A single semiconductor device 40 may provide one arm, or may provide multiple arms. In FIG. 14, for convenience, the insulating base material 451 that is included in the substrate 45 and the encapsulant 47 are omitted from the illustration.

The semiconductor module 30, like in the preceding embodiment, includes the semiconductor elements 41 and 42 and the current paths 43 and 44. The semiconductor element 41 is included in the inverter 21 (8), and the semiconductor element 42 is included in the inverter 22 (9). The semiconductor element 41 includes 41UH and 41UL, which are included in the upper and lower arm circuits 8HL of the U1 phase; 41VH and 41VL, which are included in the upper and lower arm circuits 8HL of the V1 phase; and 41WH and 41WL, which are included in the upper and lower arm circuits 8HL of the W1 phase. The semiconductor element 42 includes 42UH and 42UL, which are included in the upper and lower arm circuits 9HL of the U2 phase; 42VH and 42VL, which are included in the upper and lower arm circuits 9HL of the V2 phase; and 42WH and 42WL, which are included in the upper and lower arm circuits 9HL of the W2 phase.

The semiconductor elements 41 and 42 are arranged in the X-direction. The semiconductor element 41 and the semiconductor element 42 are alternately arranged in the X-direction. The semiconductor elements 41 and 42 are arranged so that elements whose ON period at least partially overlaps are adjacent to each other. In the example shown in FIG. 14, the upper arm elements 41H and 42H of the common phase are arranged adjacent to each other, and the lower arm elements 41L and 42L of the common phase are also arranged adjacent to each other.

Specifically, the semiconductor element 42UH is arranged adjacent to the semiconductor element 41UH. The semiconductor element 42VH is arranged adjacent to the semiconductor element 41VH. The semiconductor element 42WH is arranged adjacent to the semiconductor element 41WH. The semiconductor element 42UL is arranged adjacent to the semiconductor element 41UL. The semiconductor element 42VL is arranged adjacent to the semiconductor element 41VL. The semiconductor element 42WL is arranged adjacent to the semiconductor element 41WL. The semiconductor module 30 includes a semiconductor module 30U that provides the U1 and U2 phases of the inverters 21 and 22, a semiconductor module 30V that provides the V1 and V2 phases of the inverters 21 and 22, and a semiconductor module 30W that provides the W1 and W2 phases of the inverters 21 and 22. The semiconductor modules 30U, 30V, and 30W are arranged in the X-direction.

As in the preceding embodiment, the current path 43 includes the semiconductor element 41. The current path 44 includes the semiconductor element 42. The current paths 43 and 44 are arranged side by side in the X-direction, running parallel to each other such that the currents flowing through them are in opposite directions and face each other. Specifically, the current paths 43H and 44H of the common phase run parallel to each other. The current paths 43L and 44 of the common phase run parallel to each other. The arrangement of the P terminal 46P and the output terminals 461A and 462A is reversed in the Y-direction between the current path 43H and the current path 44H, so that the directions of currents flow in these sections are opposite to each other. Similarly, between the current path 43L and the current path 44L, the arrangement of the N terminal 46N and the output terminals 461A and 462A is reversed in the Y-direction so that the directions of current flow in these sections are opposite to each other.

### (Summary of the Second Embodiment)

The power conversion apparatus 20 of the present embodiment also includes two inverters 21 and 22 (8 and 9) that are connected to the common rotating electric machine 3. The semiconductor modules 30 that are included in the inverters 21 and 22 are provided with the semiconductor elements 41 and 42, as well as the current paths 43 and 44. In the X-direction, adjacent to the semiconductor element 41 included in the inverter 21, there is a semiconductor element 42 included in the inverter 22, positioned such that at least a part of its ON period overlaps with the ON period of the semiconductor element 41. In addition, the current path 43 including the semiconductor element 41 and the current path 44 including the semiconductor element 42 are arranged in a predetermined direction so as to run parallel to each other, with the currents flowing in opposite directions and facing each other.

With the above arrangement, when both adjacent semiconductor elements 41 and 42 are ON, the current flowing through the current path 43 and the current flowing through the current path 44 flow in opposite directions, facing each other. Therefore, by canceling out the magnetic flux, the inductance can be reduced.

The semiconductor element 41 may be included in a predetermined phase of the inverter 21, and the semiconductor element 42 may be included in a predetermined phase of the inverter 22. In other words, the adjacent semiconductor elements 41 and 42 may be included in a common phase in the inverters 21 and 22, for example, the U1 and U2 phases. When both semiconductor elements 41 and 42 are turned on and current flows through the common phase of inverters 21 and 22, the current flowing through the current path 43 and the current flowing through the current path 44 are in opposite directions, facing each other. Therefore, by canceling out the magnetic flux, the inductance can be reduced.

The dashed arrows shown in FIG. 14 indicate the current that flows when the upper arm elements of the phases U1 and U2 and the lower arm elements of the phases W1 and W2 are turned on. In other words, FIG. 14 indicates the current that flows when the semiconductor elements 41UH, 42UH, 41WL, and 42WL are turned on. The current flowing through the current path 43H, which includes the semiconductor element 41UH, and the current flowing through the current path 44H, which includes the semiconductor element 42UH, flow in opposite directions facing each other. Therefore, by canceling out the magnetic flux, the inductance can be reduced. The current flowing through the current path 43L, which includes the semiconductor element 41WL, and the current flowing through the current path 44L, which includes the semiconductor element 42WL, flow in opposite directions facing each other. Therefore, by canceling out the magnetic flux, the inductance can be reduced.

The adjacent semiconductor elements 41 and 42 are not limited to a common phase. It is sufficient if the semiconductor element 42, which is included in the inverter 22 and whose ON period at least partially overlaps with the ON period of the semiconductor element 41 included in the inverter 21, is positioned adjacent to the semiconductor element 41. For example, next to the semiconductor element 41, the semiconductor element 42 that provides a phase different from that of the semiconductor element 41 may be arranged, with at least part of the ON period of the semiconductor element 42 overlapping with the ON period of the semiconductor element 41. Then, the current paths 43 and 44 may be arranged in parallel so that the currents flowing through them are in opposite directions and face each other.

### Other Embodiments

The disclosure in this specification and drawings is not limited to the illustrated embodiments. The disclosure encompasses the illustrated embodiments as well as modifications thereof made by those skilled in the art based on these embodiments. For example, the disclosure is not limited to the combinations of components and/or elements shown in the embodiments. The disclosure can be implemented in various combinations. The disclosure may include additional parts that can be added to the embodiments. The disclosure includes embodiments in which components and/or elements of the embodiments are omitted. The disclosure encompasses the replacement or combination of components and/or elements between one embodiment and another embodiment. The technical scope of the disclosure is not limited to the descriptions of the embodiments. Some of the technical scope disclosed is indicated by the description of the claims, and should further be understood to include all modifications within the meaning and scope equivalent to the description of the claims.

The disclosure in the specification, drawings, and the like is not limited by the description of the claims. The disclosure in the specification, drawings, and the like encompasses the technical concept described in the claims and further extends to a more diverse and broader range of technical concepts than those described in the claims. Therefore, without being bound by the descriptions of the claims, various technical concepts can be extracted from the disclosures in the specification, drawings, and the like.

When an element or layer is referred to as being “on,” “connected to,” “attached to,” or “joined to” another element or layer, it may be directly on, connected, attached, or joined to the other element or layer, and it is also possible that an intervening element or layer may be present. In contrast, when an element is referred to as being “directly on,” “directly connected to,” “directly attached to,” or “directly joined to” another element or layer, no intervening element or layer is present. Other terms used to describe relationships between elements should be interpreted in a similar manner (for example, “between” versus “directly between,” “adjacent” versus “directly adjacent,” and so on). As used in this specification, the term “and/or” includes any and all combinations of one or more of the associated listed items.

Spatially relative terms such as “inner,” “outer,” “back,” “lower,” “below,” “upper,” “above,” and the like are used herein to facilitate description of the relationship of one element or feature to another element or feature as illustrated. The spatially relative terms may be intended to encompass different orientations of the device in use or operation, in addition to the orientation depicted in the drawings. For example, if the device in the drawings is turned over, an element described as being “below” or “directly below” another element or feature would then be oriented as “above” the other element or feature. Therefore, the term “below” can encompass both upward and downward orientations. This device may be oriented in other directions (it may be rotated 90 degrees or in other directions), and the spatially relative descriptors used in this specification are to be interpreted accordingly.

What is claimed is:

1. A semiconductor module forming two inverters configured to be connected to a common rotating electric machine, the semiconductor module comprising:
a first semiconductor element included in a first inverter that is one of the two inverters;
a second semiconductor element included in a second inverter that is another of the two inverters, the second semiconductor element configured to have at least a portion of an ON period that overlaps with an ON period of the first semiconductor element;
a first current path including the first semiconductor element; and
a second current path including the second semiconductor element, wherein
the second semiconductor element is adjacent to the first semiconductor element in a predetermined direction, and
the first current path and the second current path are disposed side by side in the predetermined direction, such that a direction of current flow through the first current path and a direction of current flow through the second current path are opposite to each other.

2. The semiconductor module according to claim 1, wherein
the first semiconductor element is included in a predetermined phase of the first inverter, and
the second semiconductor element is included in a predetermined phase of the second inverter corresponding to the predetermined phase of the first inverter.

3. The semiconductor module according to claim 2, wherein
the first inverter is configured to be connected to an end of a winding of the rotating electric machine,
the second inverter is configured to be connected to another end of the winding,
the first inverter and the second inverter are switchable between a star connection drive mode and an open connection drive mode,
the star connection drive mode is a mode in which the second inverter establishes a neutral point, and
the open connection drive mode is a mode in which the neutral point established by the second inverter is disconnected, and a voltage applied to each phase winding of the rotating electric machine is individually controlled.

4. The semiconductor module according to claim 3, wherein
one of the first semiconductor element and the second semiconductor element is an upper arm element, and
another of the first semiconductor element and the second semiconductor element is a lower arm element.

5. The semiconductor module according to claim 4, further comprising:
at least one semiconductor device including
the first semiconductor element,
the second semiconductor element,
a high-potential power supply terminal,
a low-potential power supply terminal disposed side by side with the high-potential power supply terminal in the predetermined direction,
a first output terminal corresponding to the high-potential power supply terminal, and
a second output terminal corresponding to the low-potential power supply terminal, wherein
one of the first current path and the second current path includes the high-potential power supply terminal, the upper arm element, and the first output terminal, and
another of the first current path and the second current path includes the low-potential power supply terminal, the lower arm element, and the second output terminal.

6. The semiconductor module according to claim 4, further comprising:
semiconductor devices including a first semiconductor device and a second semiconductor device, each of which includes the first semiconductor element, the second semiconductor element, the first current path, and the second current path, wherein the first semiconductor element of the first semiconductor device is the upper arm element in the first inverter,
the second semiconductor element of the first semiconductor device is the lower arm element in the second inverter,
the first semiconductor element of the second semiconductor device is the lower arm element in the first inverter,
the second semiconductor element of the second semiconductor device is the upper arm element in the second inverter,
the first semiconductor device is included in a phase of the first inverter,
the second semiconductor device is included in a phase of the second inverter corresponding to the phase of the first inverter, and
a direction of current flow through the first current path of one of the first semiconductor device and the second semiconductor device and a direction of current flow through the second current path of another of the first semiconductor device and the second semiconductor device are opposite to each other.

7. The semiconductor module according to claim 6, wherein
the first semiconductor device and the second semiconductor device are disposed side by side in the predetermined direction, such that respective upper arm elements or respective lower arm elements of the first semiconductor device and the second semiconductor device are adjacent to each other in the predetermined direction.

8. The semiconductor module according to claim 3, wherein
both the first semiconductor element and the second semiconductor element are either upper arm elements or lower arm elements.

9. The semiconductor module according to claim 1, wherein
each of the first semiconductor element and the second semiconductor element is a MOSFET located at a SiC substrate.

10. A power conversion apparatus comprising:
a first inverter configured to be connected to a rotating electric machine;
a second inverter configured to be connected to the rotating electric machine, wherein
the first inverter and the second inverter include a semiconductor module,
the semiconductor module includes:
a first semiconductor element included in a first inverter;
a second semiconductor element included in a second inverter, the second semiconductor element configured to have at least a portion of an ON period that overlaps with an ON period of the first semiconductor element;
a first current path including the first semiconductor element; and
a second current path including the second semiconductor element,
the second semiconductor element is adjacent to the first semiconductor element in a predetermined direction, and
the first current path and the second current path are disposed side by side in the predetermined direction, such that a direction of current flow through the first current path and a direction of current flow through the second current path are opposite to each other.

11. The power conversion apparatus according to claim 10, wherein
the first inverter configured to be connected to an end of the winding of the rotating electric machine,
the second inverter configured to be connected to another end of the winding,
the first inverter and the second inverter are switchable between a star connection drive mode and an open connection drive mode,
the star connection drive mode is a mode in which the second inverter establishes a neutral point,
the open connection drive mode is a mode in which the neutral point established by the second inverter is disconnected, and a voltage applied to each phase winding of the rotating electric machine is individually controlled,
the first semiconductor element is included in a predetermined phase of the first inverter, and
the second semiconductor element is included in a predetermined phase of the second inverter corresponding to the predetermined phase of the first inverter.
